(19) United States
(12) Patent Application Publication
(10) Pub. No.: US 2016/0033553 A1
(43) Pub. Date: Feb. 4, 2016

(54) INTELLIGENT ELECTRICAL CIRCUIT DIGITAL AMPERAGE DISPLAY INTERFACE

(71) Applicant: Rick Varone, Smithtown, NY (US)

(72) Inventor: Rick Varone, Smithtown, NY (US)

(21) Appl. No.: 14/675,882

(22) Filed: Apr. 1, 2015

Related U.S. Application Data
(60) Provisional application No. 62/032,119, filed on Aug. 1, 2014.

(51) Int. Cl. G01R 13/02; G01R 19/00

(52) U.S. Cl. CPC G01R 13/02; G01R 19/0092

(57) ABSTRACT

An intelligent electrical circuit digital amperage display interface apparatus is disclosed. In use, the old style circuit breaker is replaced with the new apparatus for connecting electrical panels and using the apparatus of the present invention, displays the amperage that travels through a standard circuit breaker out to a device under use which shows the load on that circuit's line, twenty-four hours a day. In use, the apparatus allows the user (homeowner, landlord, utilities staff and anyone else) the capability to see what the amperage being used at any given moment in time as that circuit is being used or not. Additionally, a digital display integration interface is provided within the electrical circuit breaker for displaying to a user the smallest of amperage to the largest of amperage that is being used on any given circuit.

### RELATED APPLICATIONS

This application claims benefit of priority to U.S. Provisional Patent Application No. 62/032,119 entitled “Intelligent Electrical Circuit Digital Amperage Display Interface” filed Aug. 1, 2014, the aforementioned priority application being hereby incorporated by reference in its entirety.

### TECHNICAL FIELD

The present invention relates to an improvement in an electrical circuit breaker system. More specifically, a system for the inline capture, transmission and display of amperage utilization, statistics, usage and storing of current amperage data, while simultaneously providing the functionality of standard electrical circuit breaker connectivity providing electrical service to a device at an end of a circuit.

### BACKGROUND ART

Human activities in the home (i.e., those associated with home energy use) are directly responsible for 28% of U.S. energy consumption. Most people, however, are unaware of how their daily activities affect the environment or how often they engage in those activities. Feedback regarding energy consumption, which can provide such awareness, has been shown to be one of the most effective strategies in reducing electricity usage in the home. Thus, it would be desirable to provide personal, relevant feedback about energy usage in real-time, for a variety of energy consuming activities.

Energy monitoring devices typically require professional installation to avoid concerns about the safety of a homeowner who might attempt the job, because the sensors are typically installed around a hot and/or neutral power feeds coming into the home in the main circuit breaker box. Most homeowners are neither trained for this type of installation nor confident that they can accomplish the installation without possibly electrocuting themselves or causing other damage. Accordingly, it would be desirable to employ a current/power interface apparatus that can easily be installed by an unskilled homeowner and which can enable widespread exploration of electricity monitoring applications.

Installation of a power monitoring device by an unskilled person should be safe and relatively easy. It should be possible to use such an apparatus for many applications requiring electrical current and/or power usage. The apparatus should be able to measure energy used by a structure, effectively taking the place of a conventional electromechanical or electronic watt-hour meter. A further benefit of using a current/power interface would be to provide time-of-day monitoring of energy consumption, to enable lower cost energy rates to be achieved at minimal cost to both the power utility company and the owner of a structure. These and other applications of a safe and accurate a current/power interface apparatus will be evident from the following disclosure.

### SUMMARY OF THE INVENTION

An intelligent electrical circuit digital amperage display interface apparatus is disclosed. In use, the old style circuit breaker is replaced with the new apparatus for connecting electrical panels and using the apparatus of the present invention displays the amperage that travels through a standard circuit breaker out to a device under use which shows the load on that circuit's line, twenty-four hours a day.

Using this apparatus allows the user (homeowner, landlord, utilities staff and anyone else) the capability to see what the amperage being used at any given moment in time as that circuit is being used or not. A digital display integration interface is provided within the electrical circuit breaker for displaying the smallest of amperage to the largest of amperage that is being used on any given circuit.

The apparatus may be installed in any given electrical panel by simply connecting or snapping the apparatus in the electrical circuit breakers standard spot within the electrical panel. More particularly, it replaces the prior art standard circuit breaker that has no intelligence. There is no need for an electrician to install it, it is simple even for a homeowner that has no electrical installation skills. In use, the device will tell the user immediately how much amperage is being used at that given moment. The device can provide the amperage data to a central location to gather the information to review all amperage being utilized in that location.

### DESCRIPTION OF THE DRAWINGS

In accordance with these and other objects, which will become apparent hereinafter, the instant invention will now be described with particular reference to the accompanying drawings.

FIG. 1 is a graphical illustration of one type of prior art circuit breaker; and

FIG. 2 is a block diagram of an intelligent electrical circuit digital amperage display interface apparatus in accordance with the present invention.

### DESCRIPTION OF EMBODIMENTS

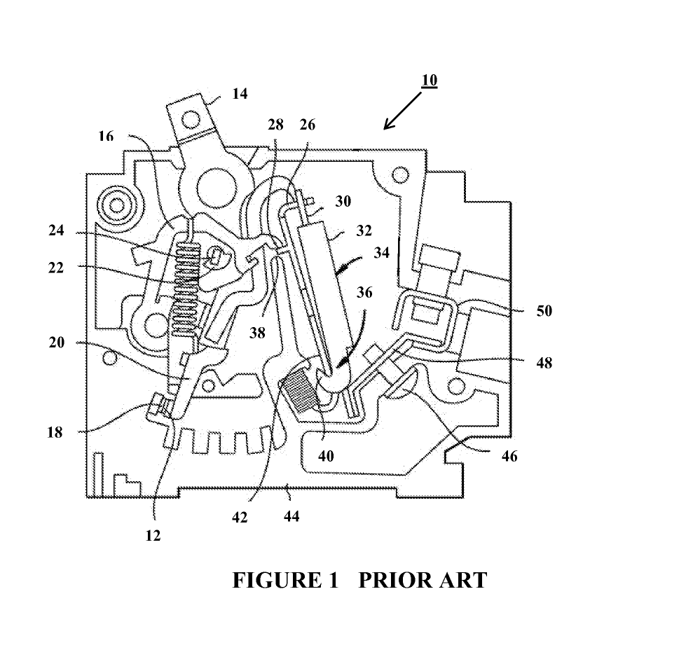

Referring now to FIG. 1 there is shown a prior art circuit breaker 10. The circuit breaker 10 is designed for use in a single-pole electronic circuit breaker used in a conventional electric circuit panel (not shown). The circuit breaker 10 includes a tripping unit 34 having a magnet 32, a bimetal member 30 received alongside of the magnet 32, and an armature 26. The armature 26 is pivotable at pivot location 36 on the magnet 32. More specifically, the pivot location 36 is formed on the magnet 32 by tabs 40 formed on either side of the magnet 32. The armature 26 includes tabs 42, which may be shoulders formed on the armature 26 which may rest in a slot formed by the tabs 40. Additionally, the armature 26 may include an engagement portion which is engageable with the bimetal member 30 at a moveable end of the bimetal member. A spring may be provided on a spring receiver of the armature 26 to bias the armature 26 away from the magnet 40.

Referring once again to FIG. 1, the armature 26 may also include a latching surface 28 formed on a tab extending from a body of the armature 26, which is adapted to engage a tripping surface on a cradle 16. In operation, when a persistent over current situation is encountered, an engaging portion will be engaged and contacted by the moveable end of the bimetal member 30 as it moves closer to the magnet 40. This disengages the latching surface 28 from the tripping surface of the cradle 16 and thereby trips the circuit breaker 10 by causing the cradle 16 to rotate clockwise and move a contact arm 20 and a moveable contact 12 away from a stationary contact 18. As shown in FIG. 1, a tab 24 on the contact arm 20 may rotate within a hole 22 in the backside of handle 14. An electrical strap 48 securely connects the load terminal 50 to the first end of the bimetal member 30. A calibration screw 46 is provided and engages the electrical strap 48 and functions to calibrate a response of the tripping unit 34. Housing portion 44 retains the various components (e.g., handle 14, magnet 40, load terminal 50, etc.), in pockets formed by interaction of the housing portion 44 and a conventional cover portion (not shown).

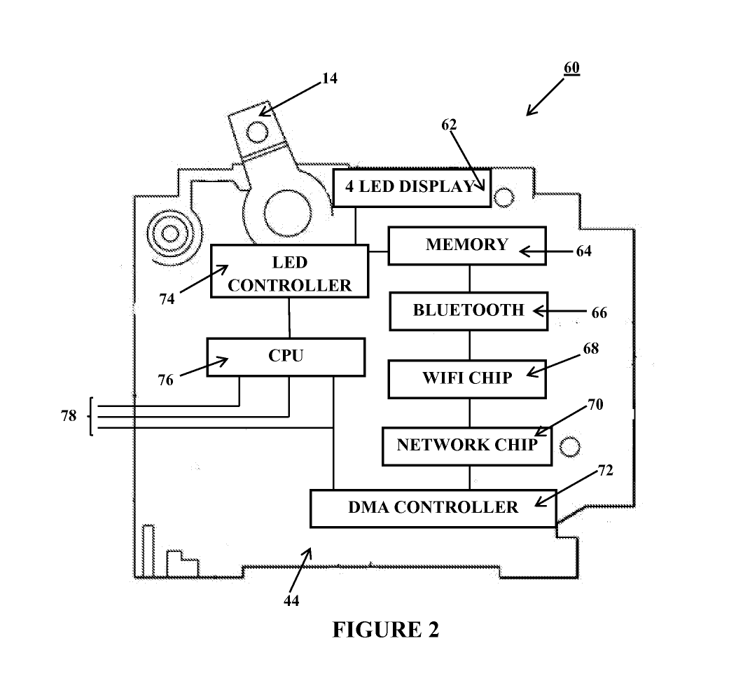

Referring now to FIG. 2, there is shown an intelligent electrical circuit digital amperage display interface apparatus 60 in accordance with the present invention. The apparatus 60 is to be used in place of the aforementioned and described electrical circuit breaker 10. By replacing the old style circuit breaker with the new apparatus 60 for connecting electrical panels using the apparatus 60 of the present invention will display the amperage that travels through a standard circuit breaker out to the device under use which shows the load on that circuit's line, twenty-four hours a day.

Using this device allows a user (homeowner, landlord, utilities staff and anyone else) the capability to see what the amperage being used at any given moment in time as that circuit is being used or not. A digital display integration interface within the electrical circuit breaker will show from the smallest of amperage to the largest of amperage that is being used on any circuit. The apparatus 60 may be installed in any given electrical panel (not shown) by simply connecting or snapping the intelligent electrical circuit digital amperage display interface or apparatus 60 in the electrical circuit breakers standard spot within the electrical panel. It replaces the prior art standard circuit breaker that has no intelligence. There is no need for an electrician to install it and is simple even for a homeowner that has no electrical installation skills. In use, the apparatus 60 will tell the user immediately how much amperage is being used at that given moment. The apparatus 60 can provide the amperage data to a central location to gather the information to review all amperage being utilized in that location.

The intelligent electrical circuit digital amperage display interface or apparatus 60 fits into any standard electrical panel (not shown). In one preferred embodiment the basic dimensions are a height of 2 and 9/16 inches, width of 1 inch, and length of 2 and ⅞ inches. The apparatus 60 has an electronic circuit (which may be built with standard technology or Micro or Nano technology inside of the apparatus 60 which senses the voltage and computes the amperage usage within/on that circuit using CPU 76. The electronic circuit housed within apparatus 60 then displays it on the LEDs 62 which is mounted on the top part of the oblong apparatus 60 which is located just to the side of the on and off switch 14 on the top side of the housing 44 of apparatus 60 as shown in FIG. 2 and at the same time stores its data in a memory chip 64 and transmits its information to a data collection device via hardwire or wireless technology. In summary, when apparatus 60 is connected inside of an electrical circuit breaker panel (not shown), it provides the intelligence within the apparatus 60 to store, display and transmit amperage data to any given Wifi, Bluetooth, and/or hardwired connected data collection device that can access the apparatus 60 using the microchips chips 66, 68 and 70 respectively, that make up the electronic circuit of apparatus 60. It should be understood that all these connections for access to the amperage utilization may be performed through wireless networks or Bluetooth technology which allows access technology as a PC, Laptop, Tablet, Intelligent Phone, or wireless printers.

The electronic circuit which is built into the apparatus 60 can transmit the data over the L1 or L2 leg (power leads of the electrical panel) 78 of the apparatus 60. Breaker panel voltage leads to a device that is connected somewhere along the electrical panels connectivity. This apparatus 60 circuit design can also send the data via Bluetooth or wirelessly connect to any other wireless device and transmit the stored (history of amperage usage report) data to a central location or to any distributed location the end-user would want to share that data with or to the backup of data collection device or a printer to view the information in paper format. The apparatus 60 further includes a DMA controller chip 72 will can capture all data and further transmit the information on each circuit and all the amperage history being used over that circuit life cycle. This can be used worldwide no matter what current 50 or 60 Hz or voltage 240, 208, 120, etc. or phase type of circuit 3 phase, 2 phase, etc.

The apparatus 60 will save lives and prevent fires within the electrical circuit panel when used. It will provide the user the amperage demand showing the user that they have too much amperage demand on that circuit. Anyone can see the amperage display if they have too much amperage demand on the circuit they will then know to cut down the amperage usage request on that circuit preventing an electrical fire. The user would then know that they put too much demand on that circuit which could cause a fire if they do not reduce that demand. For example, a user has a 20 amp circuit breaker and they use 2 blow dryers at the same time on that circuit, this would cause the circuit breaker to be overloaded and burn up or short out, The amperage draw at that given moment when the 2 blow dryers are being used draws up to 39 amps on startup and 22 amps with continuous use.

The installation of the apparatus 60 shows the connectivity of this unit is connected into the standard electrical panel breaker slot with no other limitations for connectivity to provide the new amperage view 62 of the apparatus 60. It may be envisioned that the electronic circuit shown by the block diagram of FIG. 2 of apparatus 60 may be fully incorporated into a single integrated intelligent circuit or IIC. The IIC has leads 78 coming from the main power of the circuit breaker which feeds the circuit board and it has a ground wire that goes to ground wire (not shown). The neutral wire (one of the three wires 78 shown in FIG. 2) also goes into the integrated intelligent circuit to scan that segment of the power leads for that amperage usage. This makes the apparatus's 60 IIC design for worldwide use in regard to monitoring, viewing and collecting amperage statistics on each and every circuit. The standard electrical circuit breaker is not made for this market and does not have the additional intelligent of apparatus 60 within the existing device. Once the homeowner or electrician installs the apparatus 60 into the electrical panel they will see immediately if there is any amperage on the line being used. Standard breakers are not used in the data collection, monitoring or display of any amperage as they are used. Standard electrical circuit breakers in the electrical panels today show these standard breakers are not part of this vertical marketplace.

It is contemplated for embodiments of the invention to extend to individual elements and concepts described herein, independently of other concepts, ideas or system, as well as for embodiments to include combinations of elements recited anywhere in this application. Although illustrative embodiments of the invention have been described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mention of the particular feature. Therefore, the absence of describing combinations should not preclude the inventor from claiming rights to such combinations. Although, the present invention has been described with reference to specific exemplary embodiments, it will be evident that the various modifications and changes can be made to these embodiments without departing from the broader spirit of the invention. Accordingly, the specification and drawings are to be regarded in an illustrative sense rather than in a restrictive sense.

What is claimed is:

1. A method for displaying electrical current flow supplying electrical power to a device, comprising the steps of:
replacing a circuit breaker with an intelligent circuit breaker within a standard electrical panel for a given location;
determining electrical current flowing in the main electrical lines with said intelligent circuit breaker utilizing integrated circuits housed within said intelligent circuit breaker,
displaying real time amperage data; and
providing said real time amperage data to a central location to gather the information to review all amperage being utilized in that location.

2. The method of claim 1, further comprising the step of displaying said real time amperage data using an LED display located and housed on an exterior surface of said intelligent circuit breaker.

3. The method of claim 1, further comprising the step of transmitting the real time amperage data by utilizing Bluetooth, wireless and network integrated circuit chips housed within said intelligent circuit breaker.

5. The method of claim 1, further comprising said intelligent circuit breaker a height of 2 and 9/16 inches, width of 1 inch, and length of 2 and ⅞ inches.

6. The method of claim 1, wherein the step of determining electrical current flowing in the main electrical lines with said intelligent circuit breaker comprises the step of employing an intelligent circuit breaker that includes a plurality of intelligent circuit breakers, including an intelligent circuit breaker overlying each main electrical line.

7. A system for displaying electrical current flow supplying electrical power to a device, comprising the steps of:
an intelligent circuit breaker within for replacing a circuit breaker within a standard electrical panel for a given location;
integrated circuits housed within said intelligent circuit breaker for determining electrical current flowing in main electrical lines as real time amperage data,
LEDs for displaying real time amperage data; and
a central location to gather all information to review said real time amperage data being utilized in that location.

8. The system of claim 1, further comprising using an LED display located and housed on an exterior surface of said intelligent circuit breaker for displaying said real time amperage data.

9. The system of claim 1, further comprising Bluetooth, wireless and network integrated circuit chips housed within said intelligent circuit breaker for transmitting said real time amperage data.

10. The system of claim 1, further comprising said intelligent circuit breaker having a height of 2 and 9/16 inches, width of 1 inch, and length of 2 and ⅞ inches.
